(19) United States
(12) Patent Application Publication
(10) Pub. No.: US 2015/0187688 A1
(43) Pub. Date: Jul. 2, 2015

(54) Method For Treating A Leadframe Surface And Device Having A Treated Leadframe Surface

(71) Applicant: Microchip Technology Incorporated, Chandler, AZ (US)

(72) Inventors: Joseph D. Fernandez, Chachoengsao (TH); Tarapong Soontornvipart, Chachoengsao (TH); Ekgachai Kenganantanon, Chachoengsao (TH); Oliver Mabutas, Chachoengsao (TH); Greg Perzanowski, Chandler, AZ (US)

(21) Appl. No.: 14/580,638

(22) Filed: Dec. 23, 2014

Related U.S. Application Data
(60) Provisional application No. 61/921,141, filed on Dec. 27, 2013.

(51) Int. Cl. H01L 23/495; H01L 23/31; H01L 21/56; H01L 23/00; H01L 21/48

(52) U.S. Cl. CPC H01L 23/49582; H01L 23/49541; H01L 23/49503; H01L 24/49; H01L 24/85; H01L 21/4821; H01L 21/565; H01L 23/3107; H01L 2924/01047; H01L 2224/48091; H01L 2224/48106; H01L 2224/48177

(57) ABSTRACT

A method for manufacturing an integrated circuit device is disclosed. A leadframe is provided having a die support area configured to receive an integrated circuit die and a plurality of leadframe fingers adjacent the die support area, each leadframe finger including a finger tip area at one end of the leadframe finger. The leadframe is masked such that one or more areas of the leadframe are covered and one or more areas of the leadframe are exposed, wherein for each leadframe finger, a first region of the respective finger tip area is covered by the masking and a second region of the respective finger tip area is exposed. The one or more exposed areas of the leadframe are silver plated such for each leadframe finger, the second region of the respective finger tip area is sliver plated and the first region of the respective finger tip area is not sliver plated.

### CROSS-REFERENCE To RELATED APPLICATIONS

This application claims the benefit of U.S. Provisional Application No. 61/921,141 filed on Dec. 27, 2013, which is incorporated herein in its entirety.

### TECHNICAL FIELD

The present disclosure relates to semiconductor manufacturing, in particular to a method for treating a leadframe surface.

### BACKGROUND

Many or most integrated circuit (“IC”) packages encounter delamination after the moisture loading requirement of 85° C. & 85% humidity for a duration of 168 hours, as specified by JEDEC MSL (“Moisture Sensitivity Level”) testing. In this contest, delamination refers to a separation between silver plated leadfinger areas and a mold compound, due to poor adhesion between the mold compound and the silver plated areas. Silver plating is known to having a smooth surface and thus the molding compound often does not adhere properly to the plated areas. Delamination may affect the IC packaging, resulting in package and wire bond weaknesses during reliability testing, such as when stress is applied to the package, e.g., due to moisture, temperature or humidity. Delamination may also result tin product field failures such as broken or lifted wire bonds.

Thus, there is a need for eliminating leadfinger delamination in IC packages, such as 8L SOIC & 28SOIC semiconductor device housings, for example. The JEDEC requirement mandates zero delamination on wire bonding areas using palladium coated copper wire at MSL 1, which rating indicates that the devices is not moisture sensitive. Components must be mounted and reflowed within the allowable period of time (floor life out of the bag). One way to reduce or eliminate the leadfinger delamination is to downgrade the devices to MSL3, which rating defines a maximum of one week exposure to ambient conditions before the device is assembled on a PCB. However, this typically adds substantial cost to the parts and requires special handling of the parts by the customer when removing the parts from moisture barrier bags.

Another approach intended to address this problem is to remove the silver plating on lead frame to allow the molding compound to increase the adhesion with the copper surface of the lead frame. This helps reduce the delamination but does not solve the problem, as silver plating is required for wire bonding.

### SUMMARY

According to various embodiments, leadframe delamination can be eliminated and a wire bonding process is made more reliable. According to some embodiments, a mechanical mask is used for the silver plating of the leadframe that leaves areas of copper exposed at the lead tips, which areas are thus not silver plated. This reduces the silver plating area and increases the area of copper at the lead tip to allow the mold compound (which is applied after an IC die is mounted and connected to the leadframe) to completely adhere to the copper surface of lead fingers, which may create a “locking” mechanism that does not delaminate.

One embodiment provides a method for manufacturing an integrated circuit device is disclosed. A leadframe is provided having a die support area configured to receive an integrated circuit die and a plurality of leadframe fingers adjacent the die support area, each leadframe finger including a finger tip area at one end of the leadframe finger. The leadframe is masked such that one or more areas of the leadframe are covered and one or more areas of the leadframe are exposed, wherein for each leadframe finger, a first region of the respective wire bond area is covered by the masking and a second region of the respective wire bond area is exposed. The one or more exposed areas of the leadframe are silver plated such for each leadframe finger, the second region of the respective wire bond area is sliver plated and the first region of the respective wire bond area is not sliver plated.

In a further embodiment, the method further includes attaching the integrated circuit die to the die support area of the leadframe; wire bonding the integrated circuit die to the plurality of leadframe fingers, including bonding a wire to the silver plated region of the wire bond area of each leadframe finger and applying a molding material over the leadframe and integrated circuit die such that the molding material directly contacts the first, non-silver plated region of the wire bond area of each leadframe finger.

In a further embodiment, for at least one of the plurality of leadframe fingers, the leadframe finger extends from a first end proximate the die support area of the leadframe to a second end or area further away from the die support area, and the first, non-silver plated region of the wire bond area is located at the first end of the leadframe finger proximate the die support area.

In a further embodiment, for at least one of the plurality of leadframe fingers, the first, non-silver plated region of the wire bond area is located geometrically between the second, silver plated region of the wire bond area and the die support area of the leadframe.

In a further embodiment, the masking step comprises masking the leadframe such that, for at least one of the leadframe fingers, a first region of the respective wire bond area is covered by the masking and at least two second regions of the respective wire bond area are exposed, the at least two second regions being spaced apart from each other.

In a further embodiment, the masking step comprises masking the leadframe such that, for at least one of the leadframe fingers, a first region of the respective wire bond area is covered by the masking and a pair of second regions of the respective wire bond area are exposed, with the first covered region located between the pair of second regions.

In a further embodiment, the leadframe includes at least one additional leadframe finger having a wire bond area that is either fully silver plated or fully non-silver plated.

Another embodiment provides an integrated circuit structure including a leadframe comprising a die support area configured to receive an integrated circuit die, and a plurality of leadframe fingers adjacent the die support area, each leadframe finger including a finger tip area at one end of the leadframe finger. The wire bond area of each leadframe finger includes a surface including a first region that is sliver plated, and a second region that is not sliver plated.

In a further embodiment, the integrated circuit structure further includes an integrated circuit die mounted to the die support area of the leadframe; wire bond connections between the integrated circuit die and the first, silver plated region of each wire bond area; and a molding material applied over the leadframe and integrated circuit die, wherein the molding material directly contacts the second, non-silver plated region of each wire bond area.

In a further embodiment, for at least one of the plurality of leadframe fingers, the leadframe finger extends from a first end proximate the die support area of the leadframe to a second end or area further away from the die support area, and the second, non-silver plated region of the wire bond area is located at the first end of the leadframe finger proximate the die support area.

In a further embodiment, for at least one of the plurality of leadframe fingers, the second, non-silver plated region of the wire bond area is located geometrically between the first, silver plated region of the wire bond area and the die support area of the leadframe.

In a further embodiment, for at least one of the plurality of leadframe fingers, the surface of the wire bond area includes at least two second, non-silver plated regions that are spaced apart from each other.

In a further embodiment, for at least one of the plurality of leadframe fingers, the surface of the wire bond area includes a pair of second, non-silver plated regions, with the first, silver plated region located between the pair of second, non-silver plated regions.

In a further embodiment, the leadframe includes at least one additional leadframe finger having a wire bond area that is either fully silver plated or fully non-silver plated.

### BRIEF DESCRIPTION OF THE FIGURES

Example embodiments are discussed below with reference to the drawings, in which:

FIG. 1 shows an example leadframe for mounting an integrated circuit die to form an integrated circuit device, e.g., a chip;

FIG. 2A illustrates an existing or conventional masking for silver plating the leadfinger tip areas of a leadframe;

FIG. 2B shows the resulting silver plating of the leadframe using the existing or conventional masking shown in FIG. 2A;

FIG. 3A illustrates an example masking configuration for silver plating the leadfinger tip areas of a leadframe, according to a first example embodiment;

FIG. 3B shows the resulting silver plating of the leadframe using the masking shown in FIG. 3A, which defines non-silver plated areas on the leadfinger tips for improved adhesion with a mold compound;

FIG. 4A illustrates another example masking configuration for silver plating the leadfinger tip areas of a leadframe, according to a second example embodiment;

FIG. 4B shows the resulting silver plating of the leadframe using the masking shown in FIG. 4A, which defines non-silver plated areas on the leadfinger tips for improved adhesion with a mold compound; and

FIG. 5 illustrates an example process for manufacturing an integrated circuit device having a die mounted to a leadframe, a mold compound formed over the structure, and an improved adhesion between the mold compound and non-silver plated areas of the leadfinger tips, according to an example embodiment.

### DETAILED DESCRIPTION

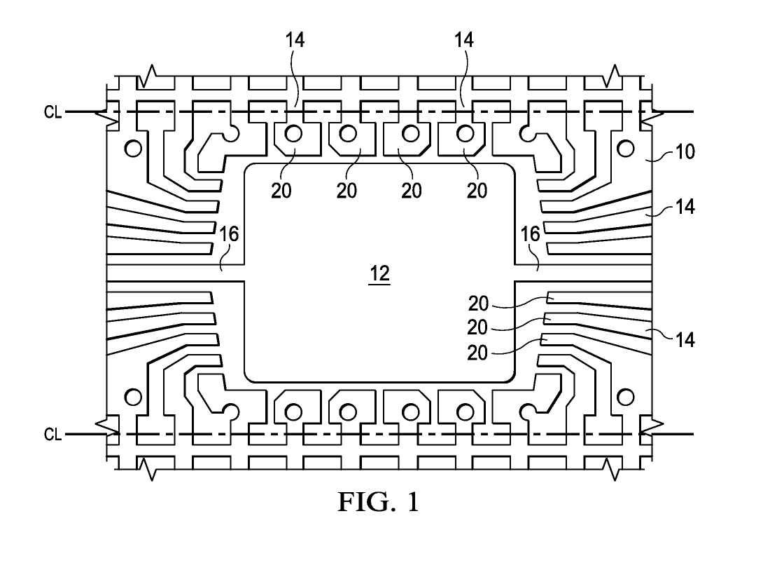

FIG. 1 shows an example leadframe 10 prior to being processed, e.g., by silver plating the leadframe, mounting an integrated circuit (IC) die to the leadframe, wire bonding the IC die to the leadframe, molding the leadframe, and cutting the leadframe out of a larger leadframe array, e.g., along example cut lines CL. The example leadframe 10 shown in FIG. 1 is formed with a pattern that defines a die support region or plate 12 configured to support an integrated circuit die mounted thereto, a plurality of leadfingers 14 arranged around a periphery of (and spaced apart from) the die support region 12, and one or more connecting structures 16 that physically connect the die support region 12 to the rest of the leadframe 10 that includes the leadfingers 14. Each leadfinger 14 includes a tip region 20 proximate the die support region 12 and configured for an electrical connection, e.g., by wire bond, to an integrated circuit die mounted on the die support region 12.

Leadframe 10 may be formed from any suitable material, e.g., copper or a copper alloy, a ferrous alloy containing nickel, cobalt, or chromium, nickel or a nickel alloy, or any other suitable material. A copper leadframe is discussed herein for the purposes of discussion; however, it should be understood that the concepts discussed herein are not limited to a copper leadframe but rather apply to leadframes of any other suitable materials. In addition, the shape and pattern of leadframe 10 shown in FIG. 1 is an example only; leadframe 10 may also may have any other suitable pattern and shape, including any other suitable arrangement of die support region or plate 12, leadfingers 14, and connecting structures 16.

Leadfinger tip areas 20 may be coated or plated with any suitable material to provide a desired electrical and mechanical contact (e.g., via wire bond) between the IC die mounted to the leadframe 10 and the material of the leadfingers 14 (in the example discussed herein, copper). In some embodiments, e.g., as discussed herein, leadfinger tip areas 20 may be coated or plated with silver. In other embodiments, e.g., as discussed herein, leadfinger tip areas 20 may be coated or plated with another suitable material.

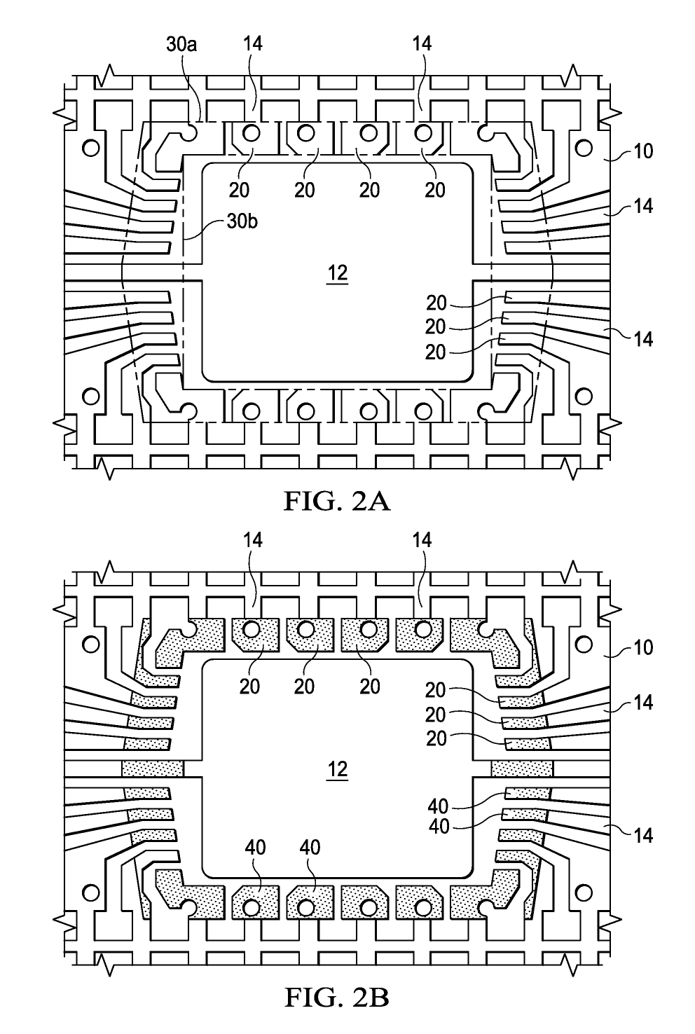

FIGS. 2A and 2B illustrate an existing or conventional technique for silver plating the leadfinger tip areas 20 of leadframe 10. To apply the silver plating, leadframe 10 is masked using any suitable masking equipment and technique, and the silver plating is then applied to the exposed areas of the leadframe 10. FIG. 2A shows an example masking, in which the areas inside mask boundary 30b and outside mask boundary 30a are masked, thus exposing the areas of leadframe 10 between boundary lines 30a and 30b. FIG. 2B shows the result of the silver plating using the masking configuration of FIG. 2A. As shown, a silver plated region 40 is defined on each leadfinger tip 20.

FIGS. 2A and 2B illustrate an existing or conventional technique for silver plating the leadfinger tip areas 20 of leadframe 10. To apply the silver plating, leadframe 10 is masked using any suitable masking equipment and technique, and the silver plating is then applied to the exposed areas of the leadframe 10. FIG. 2A shows an example masking, in which the areas inside mask boundary 30b and outside mask boundary 30a are masked, thus exposing the areas of leadframe 10 between boundary lines 30a and 30b. FIG. 2B shows the result of the silver plating using the masking configuration of FIG. 2A. As shown, a silver plated region 40 is defined on each leadfinger tip 20.

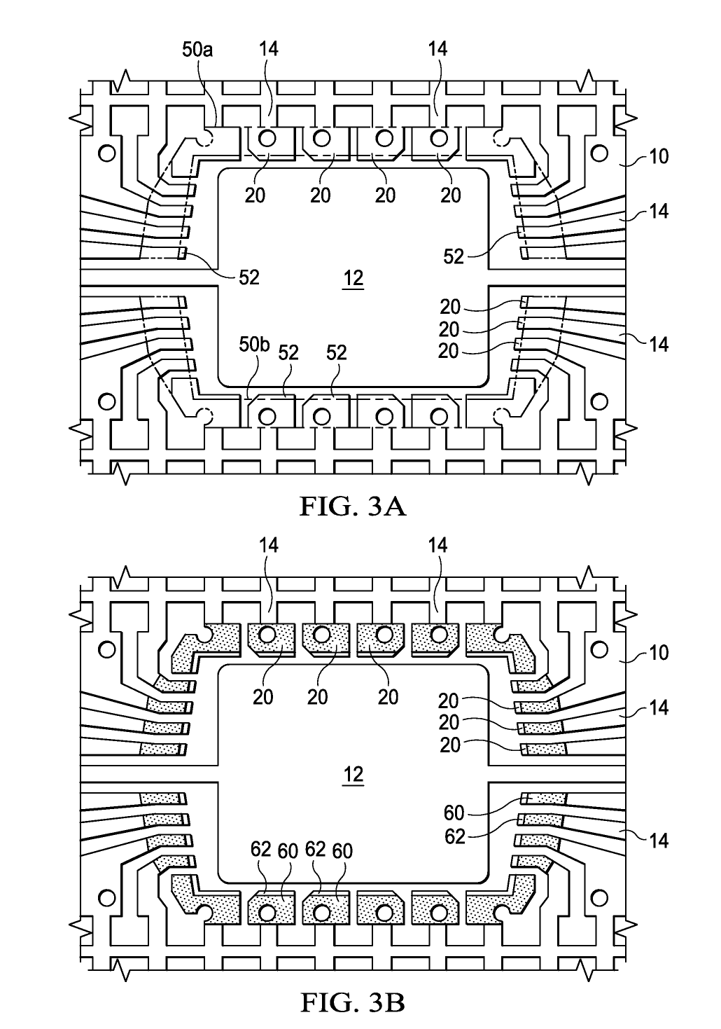

FIGS. 3A and 3B illustrate an example of an improved technique for silver plating the leadfinger tip areas 20 of leadframe 10, according to a first example embodiment of the present invention. To apply the silver plating, leadframe 10 is masked using one or more physical, or mechanical, masks such that for each leadframe finger 14, a first region of the finger tip area 20 is masked and at least one second region of the finger tip area 20 is exposed through the mask. FIG. 3A shows an example of a physical mask that defines a mask pattern including a pair of openings defined by boundary lines 50a and 50b. According to this masking, for each leadframe finger 14, a region of the finger tip area 20 closest to the die support region 12, indicated as region 52, is masked to prevent silver plating of that region. As shown, the masked region 52 of each finger tip area 20 may be located inwardly of the exposed area of the respective finger tip area 20, with respect to the die support region 12.

FIG. 3B shows the result of the silver plating using the example mask pattern of FIG. 3A. As shown, a silver plated region 60 is defined on each leadfinger tip 20, and a non-silver plated region 62 (corresponding to masked regions 52 shown in FIG. 3A) is defined on each leadfinger tip 20 inwardly of the silver plated region 60, with respect to the die support region 12. In some embodiments, the mask pattern may define, on each finger tip area 20, an exposed region located between a pair of masked regions, such that after the silver plating, each finger tip area 20 includes a silver plated region 60 located between two non-silver plated regions 62, with one non-silver plated region 62 located inwardly of the silver plated region 60 and the other non-silver plated region 62 located outwardly of the silver plated region 62, with respect to the die support region 12.

In some embodiments, the mask fully covers or fully exposes at least one leadfinger tip 20, such that at least one leadfinger tip 20 is fully silver plated or fully non-silver plated. In addition, the mask may or may not expose area(s) of any connecting regions 16, depending on the particular embodiment.

The non-silver plated regions 62 of leadfinger tips 20 reduces the silver plated areas on the leadfinger tips 20, and provides an area for direct contact between the non-plated copper surface of the leadfinger tip 20 and the mold compound that is subsequently applied to the structure after an IC die is mounted to the leadframe 10 and electrically connected (e.g., wire bonded) to each leadfinger tip 20 at the silver plated region 60 on each tip 20. The mold compound adheres reliably to the exposed copper of the leadfinger tip 20 (at the non-silver plated regions 62) and does not delaminate, unlike the interface between the mold compound and silver plating, which tends to delaminate over time. In particular, by providing a non-silver plated region 62 at the end portion of each leadfinger tip 20, i.e., beyond the respective silver plated region 60 in the direction toward the very end of the tip 20 (proximate die support region 12), the direct contact between the non-silver plated region 62 and mold compound creates a “locking” mechanism for the leadfinger 14 that reduces or prevents delamination of the respective silver plated region 60 from the mold compound. This secure connection between the leadfinger tip 20 and mold compound allows for reliable wire bonding (e.g., using palladium coated copper or gold wire bonding) of the IC die to the leadfingers 14 over time.

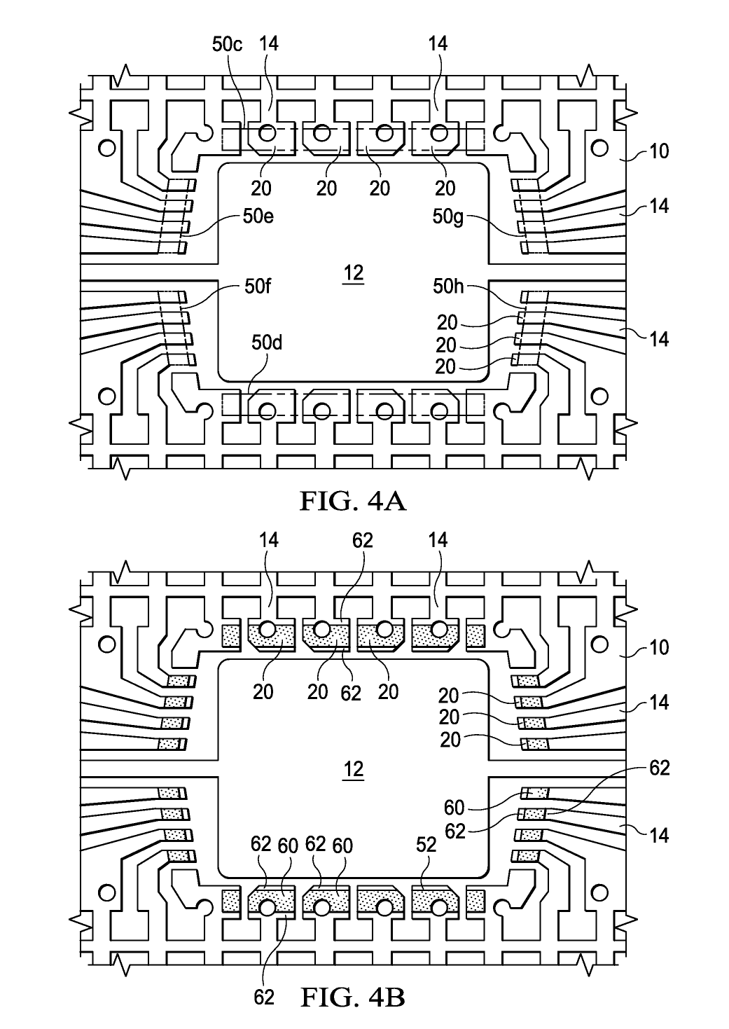

FIGS. 4A and 4B illustrate another example of an improved technique for silver plating the leadfinger tip areas 20 of leadframe 10, according to a second example embodiment of the present invention. As shown in FIG. 4A, the mask defines a number of openings 50c-50h, which expose particular areas of the underlying leadframe 10. In particular, the mask pattern is such that, for each leadframe finger tip are 20, a first region is exposed and a pair of second regions on either side of the first region are covered by the mask.

FIG. 4B shows the result of the silver plating using the example mask pattern of FIG. 4A. As shown, each leadfinger tip area 20 includes a silver plated region 60 a pair of non-silver plated regions 62 on opposing sides of the silver plated region 60. The non-silver plated regions 62 provide areas for direct contact between the copper surface of the leadfinger tip 20 and the mold compound subsequently applied to the structure, which may create a “locking” mechanism between the leadfingers 14 and mold compound that reduces or prevents delamination of the silver plated regions 60 from the mold compound.

It should be understood that the mask patterns shown in FIGS. 3A and 4A are examples only, and the mask may have any other suitable pattern that results in one or more non-silver plated areas of individual leadfinger tip areas 20, for improved adhesion with the subsequently applied mold compound.

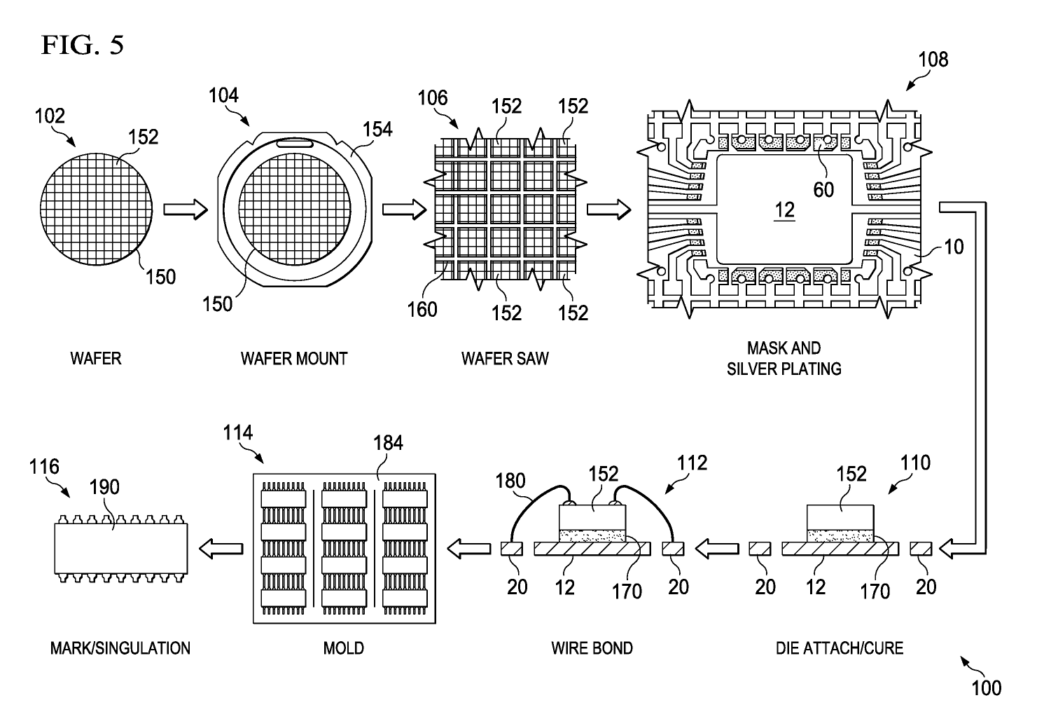

FIG. 5 illustrates an example process 100 for manufacturing an integrated circuit device 190, according to an example embodiment. A wafer 150 defining an array of IC device substrates 152 is provided at step 102. At step 104, the wafer 150 is mounted to a wafer mount 154, e.g., using epoxy and/or mount tape. At step 106, the wafer is cut using a wafer saw, as indicated by cut lines 160. At step 108, a masking and silver plating process is performed on the wafer such that the leadframe finger tips 20 of each leadframes 10 have one or more non-silver plated areas 62, e.g., as discussed above. For example, a mask such as shown in the example embodiments of FIG. 3A or 4A may be used at step 108.

At step 110, an IC die is picked and attached to the die support region 12 of each leadframe 10, e.g., using an epoxy 170 and curing process. At step 112, each die is wire bonded to the silver plated region 60 of each leadframe finger tip 20 of the respective leadframe 10, e.g., using palladium coated copper or gold wire bonds 180. At step 114, the structure is molded in a plastic or other suitable molding compound. As discussed above, the non-silver plated areas 62 of the leadframe finger tips 20 directly contact the molding compound and provide a secure adhesion, thereby locking the mold compound to the leadframe fingers 14. At step 116, the wafer is marked and singulated, resulting in a plurality of discreted IC devices/chips 190.

The teachings above may provide various advantages. First, the delamination between the leadframe and mold compound may be eliminated or substantially reduced. The resulting devices may thus be more likely to meet JEDEC MSL1 reliability standards. Further, the product reliability and lifetime of the resulting IC devices may be extended. Occurrences of lifted, broken wire bonds in field failures, and corresponding customer complaints, may be substantially reduced or eliminated. Further, the disclosed solution may provide cost savings in packing methodology, e.g., by eliminating the need for dry pack, as compared with solutions such as downgrade devices to MSL3. Finally, the production cycle time may be reduced, due to no baking process.

Although the disclosed embodiments are described in detail in the present disclosure, it should be understood that various changes, substitutions and alterations can be made to the embodiments without departing from their spirit and scope.

What is claimed is:

1. A method for manufacturing an integrated circuit device, the method comprising:
providing a leadframe comprising:
a die support area configured to receive an integrated circuit die; and
a plurality of leadframe fingers adjacent the die support area, each leadframe finger including a finger tip area at one end of the leadframe finger;
masking the leadframe such that one or more areas of the leadframe are covered and one or more areas of the leadframe are exposed, wherein for each leadframe finger, a first region of the respective finger tip area is covered by the masking and a second region of the respective finger tip area is exposed; and
silver plating the one or more exposed areas of the leadframe, such for each leadframe finger, the second region of the respective finger tip area is sliver plated and the first region of the respective finger tip area is not sliver plated.

2. The method of claim 1, further comprising:
attaching the integrated circuit die to the die support area of the leadframe;
wire bonding the integrated circuit die to the plurality of leadframe fingers, including bonding a wire to the silver plated region of the finger tip area of each leadframe finger; and
applying a molding material over the leadframe and integrated circuit die such that the molding material directly contacts the first, non-silver plated region of the finger tip area of each leadframe finger.

3. The method of claim 1, wherein, for at least one of the plurality of leadframe fingers:
the leadframe finger extends from a first end proximate the die support area of the leadframe to a second end or area further away from the die support area; and
the first, non-silver plated region of the finger tip area is located at the first end of the leadframe finger proximate the die support area.

4. The method of claim 1, wherein, for at least one of the plurality of leadframe fingers, the first, non-silver plated region of the finger tip area is located geometrically between the second, silver plated region of the finger tip area and the die support area of the leadframe.

5. The method of claim 1, wherein the masking step comprises masking the leadframe such that, for at least one of the leadframe fingers, a first region of the respective finger tip area is covered by the masking and at least two second regions of the respective finger tip area are exposed, the at least two second regions being spaced apart from each other.

6. The method of claim 1, wherein the masking step comprises masking the leadframe such that, for at least one of the leadframe fingers, a first region of the respective finger tip area is covered by the masking and a pair of second regions of the respective finger tip area are exposed, with the first covered region located between the pair of second regions.

7. The method of claim 1, wherein the leadframe includes at least one additional leadframe finger having a finger tip area that is either fully silver plated or fully non-silver plated.

8. An integrated circuit structure, comprising:
a leadframe comprising:
a die support area configured to receive an integrated circuit die; and
a plurality of leadframe fingers adjacent the die support area, each leadframe finger including a finger tip area at one end of the leadframe finger;
wherein the finger tip area of each leadframe finger includes a surface including:
a first region that is sliver plated; and
a second region that is not sliver plated.

9. The integrated circuit structure of claim 8, further comprising:
an integrated circuit die mounted to the die support area of the leadframe;
wire bond connections between the integrated circuit die and the first, silver plated region of each leadframe finger tip area; and
a molding material applied over the leadframe and integrated circuit die, wherein the molding material directly contacts the second, non-silver plated region of each leadframe finger tip area.

10. The integrated circuit structure of claim 8, wherein, for at least one of the plurality of leadframe fingers:
the leadframe finger extends from a first end proximate the die support area of the leadframe to a second end or area further away from the die support area; and
the second, non-silver plated region of the finger tip area is located at the first end of the leadframe finger proximate the die support area.

11. The integrated circuit structure of claim 8, wherein, for at least one of the plurality of leadframe fingers, the second, non-silver plated region of the finger tip area is located geometrically between the first, silver plated region of the finger tip area and the die support area of the leadframe.

12. The integrated circuit structure of claim 8, wherein, for at least one of the plurality of leadframe fingers, the surface of the finger tip area includes at least two second, non-silver plated regions that are spaced apart from each other.

13. The integrated circuit structure of claim 8, wherein, for at least one of the plurality of leadframe fingers, the surface of the finger tip area includes a pair of second, non-silver plated regions, with the first, silver plated region located between the pair of second, non-silver plated regions.

14. The integrated circuit structure of claim 8, wherein the leadframe includes at least one additional leadframe finger having a finger tip area that is either fully silver plated or fully non-silver plated.
